(19) United States
(12) Patent Application Publication
(10) Pub. No.: US 2024/0332254 A1
(43) Pub. Date: Oct. 3, 2024

(54) DISPLAY DEVICE INCLUDING A SEMICONDUCTOR LIGHT EMITTING DEVICE

(71) Applicant: LG ELECTRONICS INC., Seoul (KR)

(72) Inventors: Sangdae PARK, Seoul (KR); Dohyung LEE, Seoul (KR); Sungguk LEE, Seoul (KR); Hwankuk YUH, Seoul (KR)

(73) Assignee: LG ELECTRONICS INC., Seoul (KR)

(21) Appl. No.: 18/622,384

(22) Filed: Mar. 29, 2024

(30) Foreign Application Priority Data
Mar. 30, 2023 (KR) 10-2023-0041666

(51) Int. Cl. H01L 25/065; H01L 25/075; H01L 27/12

(52) U.S. Cl. CPC H01L 25/0652; H01L 25/0753; H01L 27/124

(57) ABSTRACT

A display device including a semiconductor light emitting device according to an embodiment can include a substrate; a transistor disposed on the substrate; a barrier wall disposed on the transistor and having an assembly hole; a semiconductor light emitting device disposed within the assembly hole; an insulating layer disposed on the semiconductor light emitting device and having a contact hole; and a first transparent connection electrode disposed on the insulating layer and electrically connecting the semiconductor light emitting device and the transistor, and the first transparent connection electrode may include a recess pattern disposed in the contact hole.

### CROSS-REFERENCE TO RELATED APPLICATION

This application claims the priority benefit of Korean Patent Application No. 10-2023-0041666 filed in the Republic of Korea on Mar. 30, 2023, the entire contents of which are hereby expressly incorporated by reference into the present application.

### BACKGROUND OF THE DISCLOSURE

### 1. Field of the Disclosure

Embodiment relates to a display device including a semiconductor light emitting device.

### 2. Background of the Related Art

Large-area displays include liquid crystal displays (LCDs), OLED displays, and Micro-LED displays.

A micro-LED display is a display using a micro-LED, which is a semiconductor light emitting device having a diameter or cross-sectional area of 100 μm or less, as a display device.

Micro-LED display has excellent performance in many characteristics such as contrast ratio, response speed, color reproducibility, viewing angle, brightness, resolution, lifespan, luminous efficiency and luminance because it uses micro-LED, which is a semiconductor light emitting device, as a display element.

In particular, micro-LED displays have the advantage of being able to separate and combine screens in a modular way, so that size or resolution can be freely adjusted and flexible displays can be implemented.

However, since large-sized micro-LED display requires millions of micro-LEDs, there is a technical problem in that it is difficult to quickly and accurately transfer micro-LEDs to a display panel.

Recently developed transfer technology includes a pick and place process, a laser lift-off method, or a self-assembly method.

Among them, the self-assembly method is a method in which the semiconductor light emitting device finds an assembly position in a fluid by itself, and is an advantageous method for realizing a large-screen display device.

However, research on a technology for manufacturing a display through self-assembly of micro-LEDs is still insufficient.

In particular, in the case of rapidly transferring millions or more semiconductor light emitting devices to a large display in the prior art, the transfer speed can be improved, but there is a technical problem in that the transfer error rate can increase and the transfer yield can decrease.

In related technologies, a self-assembly type transfer process using dielectrophoresis (DEP) has been attempted, but there is a problem in that the self-assembly rate is low due to the non-uniformity of the DEP force.

On the other hand, when connecting the upper electrode of the semiconductor light emitting device to the display panel, there is a problem in that lighting is weakened or unlit due to damage to the upper electrode due to the panel process.

For example, according to internal technology, when ITO is deposited on top of the semiconductor light emitting device chip through a thin film deposition process, due to poor adhesion characteristics between the semiconductor light emitting device chip and the ITO, defects such as cracking of the ITO occur, resulting in non-lighting or weakly lighting defects of the display panel.

In addition, in the internal technology, the ITO structure for the upper electrode may be a structure vulnerable to thermal expansion after deposition. In particular, there is a problem in that ITO cracks are generated in a stepped region, and dark spots or weak lighting defects occur due to non-lighting.

### SUMMARY OF THE DISCLOSURE

One of the technical problems of the embodiment is to prevent cracks from occurring in a transparent connection electrode connecting a semiconductor light emitting device and a transistor.

In addition, one of the technical problems of the embodiment is to alleviate external stress applied to the transparent connection electrode.

In addition, one of the technical problems of the embodiment is to improve the reliability of the electrode in a stepped region.

In addition, one of the technical problems of the embodiment is to prevent a decrease in electrical reliability even if a crack occurs in the transparent connection electrode.

The technical problems of the embodiment are not limited to those described in this section, and include those that can be grasped through the description of the invention.

The display device including a semiconductor light emitting device according to the embodiment can include a substrate; a transistor disposed on the substrate; a barrier wall disposed on the transistor and having an assembly hole; a semiconductor light emitting device disposed within the assembly hole; an insulating layer disposed on the semiconductor light emitting device and having a contact hole; and a first transparent connection electrode disposed on the insulating layer and electrically connecting the semiconductor light emitting device and the transistor. The first transparent connection electrode can include a recess pattern disposed in the contact hole.

In addition, in an embodiment, the recess pattern can be disposed to be in contact with an inner wall of the contact hole.

In addition, in the embodiment, the recess pattern comprises a plurality of pieces, and the plurality of recess patterns can be disposed symmetrically with respect to the contact hole.

In addition, in an embodiment, the contact hole includes a first contact hole disposed on a bottom surface of the contact hole and a second contact hole disposed on a side surface of the contact hole, and the second contact hole can have a predetermined slope.

In addition, in an embodiment, the recess pattern can further include a second recess pattern disposed adjacent to an outside of the contact hole.

In addition, in the embodiment, the first transparent connection electrode can include a first-first transparent connection electrode disposed outside the contact hole and a first-second transparent connection electrode disposed inside the contact hole and the recess pattern can contact the first-first transparent connection electrode and the first-second transparent connection electrode.

In addition, in an embodiment, the recess pattern can be disposed adjacent to a boundary of the contact hole.

In addition, in the embodiment, a metal pattern layer disposed on the first transparent connection electrode can be further included, and the metal pattern layer can be disposed in the contact hole.

In addition, in the embodiment, the first transparent connection electrode includes a first-first transparent connection electrode disposed outside the contact hole and a first-second transparent connection electrode disposed inside the contact hole, and the metal pattern layer can electrically connect the first-first transparent connection electrode and the first-second transparent connection electrode.

In addition, in the embodiment, the metal pattern layer may not vertically overlap the recess pattern.

### Advantageous Effects of the Disclosure

The display device including the semiconductor light emitting device according to the embodiment has a technical effect of preventing cracks of the transparent connection electrode in the contact area between the semiconductor light emitting device and the transistor.

For example, according to the embodiment, a recess pattern can be formed in the contact area to prevent cracking.

In addition, the embodiment has a technical effect of preventing damage by alleviating the stress applied to the transparent connection electrode in the contact area of the semiconductor light emitting device and the transistor.

In addition, the embodiment has a technical effect of preventing a decrease in reliability of the transparent connection electrode due to a step in the contact area.

For example, according to the embodiment, a recess pattern is formed on the inside or outside of the stepped region to prevent damage to the transparent connection electrode.

In addition, the embodiment has a technical effect of preventing a decrease in electrical reliability even when cracks occur in the contact area.

For example, the embodiment can form a metal pattern layer in the contact area to maintain electrical connection of the transparent connection electrode.

The technical effects of the embodiments are not limited to those described in this section, and include those that can be grasped through the description of the invention.

### BRIEF DESCRIPTION OF THE DRAWINGS

FIGS. 1a and 1b are views showing cracks in contact holes in closed internal technology.

FIG. 2 is a cross-sectional view of a display device including a semiconductor light emitting device according to the first embodiment.

FIG. 3 is a plan view and cross-sectional view showing area A of FIG. 2 in detail.

FIG. 4 is a plan view and a cross-sectional view of a display device including the semiconductor light emitting device according to a second embodiment.

FIG. 5 is a plan view and a cross-sectional view of a display device including the semiconductor light emitting device according to a third embodiment.

FIG. 6 is a plan view and a cross-sectional view of a display device including the semiconductor light emitting device according to a fourth embodiment.

FIG. 7 is a plan view and a cross-sectional view of a display device including the semiconductor light emitting device according to a fifth embodiment.

FIG. 8 is a plan view and a cross-sectional view of a display device including the semiconductor light emitting device according to a sixth embodiment.

FIG. 9 is a plan view and a cross-sectional view of a display device including the semiconductor light emitting device according to a seventh embodiment.

FIG. 10 is a plan view and a cross-sectional view of a display device including the semiconductor light emitting device according to an eighth embodiment.

FIG. 11 is a plan view and a cross-sectional view of a display device including the semiconductor light emitting device according to a ninth embodiment.

FIG. 12 is a plan view and a cross-sectional view of a display device including the semiconductor light emitting device according to a tenth embodiment.

FIG. 13 is a plan view and a cross-sectional view of a display device including the semiconductor light emitting device according to an eleventh embodiment.

FIG. 14 is a plan view and a cross-sectional view of a display device including the semiconductor light emitting device according to a twelfth embodiment.

### DETAILED DESCRIPTION OF THE DISCLOSURE

Hereinafter, the embodiments disclosed in the present specification will be described in detail with reference to the accompanying drawings, but the same or similar components are given the same reference sign regardless of the reference numerals, and the redundant description thereof will be omitted. The suffixes “module” and “part” for components used in the following description are given or mixed in consideration of only the ease of writing the specification, and do not have a meaning or role distinct from each other by themselves. In addition, the accompanying drawings are for easy understanding of the embodiments disclosed in the present specification, and the technical spirit disclosed in the present specification is not limited by the accompanying drawings. In addition, when an element, such as a layer, area, or substrate, is referred to as being ‘on’ another component, this includes that it is directly on the other element or there can be other intermediate elements in between. In the specification or claims, the expression of “an element A includes or comprises at least one of a, b, and/or c” may mean \textcircled{1} the element A includes or comprises “a”, \textcircled{2} the element A includes or comprises “b”, \textcircled{3} the element A includes or comprises “c”, \textcircled{4} the element A includes or comprises “a and b”, \textcircled{5} the element A includes or comprises “b and c”, \textcircled{6} the element A includes or comprises “a and c”, and \textcircled{7} the element A includes or comprises “a, b and c”. Singular expression may include or comprises plural as well as singular expression, unless the context clearly indicates otherwise. For example, the meaning of “an element A includes or comprises a structure may include or comprise the meaning of “the element A includes or comprises one or more structure”.

The display device described in this specification can include a mobile phone, a smart phone, a laptop computer, a Digital broadcasting terminal, a personal digital assistant (PDA), a portable multimedia player (PMP), a navigation, a slate PC, a tablet PC, an ultra-book, a digital TV, a desktop computer, etc. However, the element according to the embodiment described in the present specification can be applied to a device capable of displaying even a new product form to be developed later.

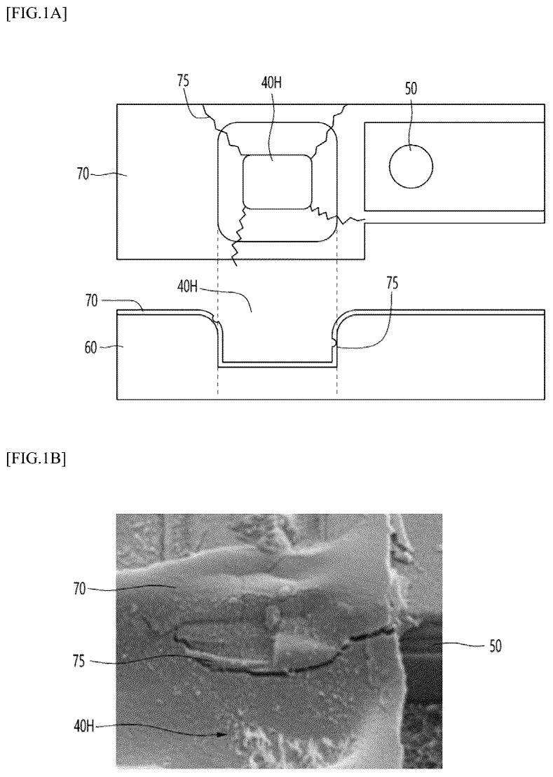

FIG. 1A is a plan view and a cross-sectional view of an ITO contact hole region in a display panel according to an undisclosed internal technology.

Referring to FIG. 1A, in the display device, the semiconductor light emitting device 50 can be connected to a transistor (not shown). An ITO upper electrode 70 can be disposed on the semiconductor light emitting device 50, and the upper electrode 70 can be connected to a transistor through a contact hole 40H.

Meanwhile, an upper portion of the semiconductor light emitting device 50 can have a height difference from that of the contact hole 40H. The ITO upper electrode 70 is disposed on an insulating layer covering the semiconductor light emitting device, since the insulating layer 60 has a step in the contact hole 40H region, the ITO upper electrode 70 can be disposed with a height corresponding to the step.

In this case, stress is concentrated on the transparent connection electrode made of ITO in the stepped region, and the electrode is cracked due to thermal expansion during the heat application process. Due to this, the semiconductor light emitting device chip and the electrode can be disconnected, which can cause a problem of lighting failure, and a problem in that electrical performance is deteriorated due to an increase in resistance.

FIG. 1B is a photograph showing a part of the crack 75 of the electrode in the display panel studied internally. Referring to FIG. 1B, as the insulating layer in the display panel has a step, the semiconductor light emitting device 50 and the ITO transparent electrode 70 connected to cover the contact hole 40H in addition have a step. Accordingly, in the stepped region, the ITO transparent electrode 70 has reduced resistance to external stress, a phenomenon in which electrodes are damaged by heat or pressure in a panel process occurs, which can cause lighting problems and performance degradation of semiconductor light emitting devices in a display panel.

For example, according to the internal technology, when ITO is deposited on top of the semiconductor light emitting device chip through a thin film deposition process, the adhesion characteristics between the semiconductor light emitting device chip and ITO are not good, defects such as tearing, cracking, or non-uniformity of the ITO pattern occur, resulting in poor or weak lighting of the display panel.

In particular, in the internal technology, the ITO structure for the upper electrode may be a structure vulnerable to thermal expansion during the baking process after deposition, in particular, there is a problem in that dark spots or weak lighting defects due to non-illumination occur because ITO cracks are generated in a side region or a contact hole region of the stepped semiconductor light emitting device chip.

In the internal technology, in order to prevent such ITO cracks, surface treatment was performed before ITO deposition and the defects were improved to some extent by conducting the ITO deposition process.

However, even if the improvement process is applied, there is a problem in that ITO cracks occur due to the condition or condition of the ITO deposition surface or the change in surface condition due to the increase in waiting time between processes in the mass production process after surface treatment.

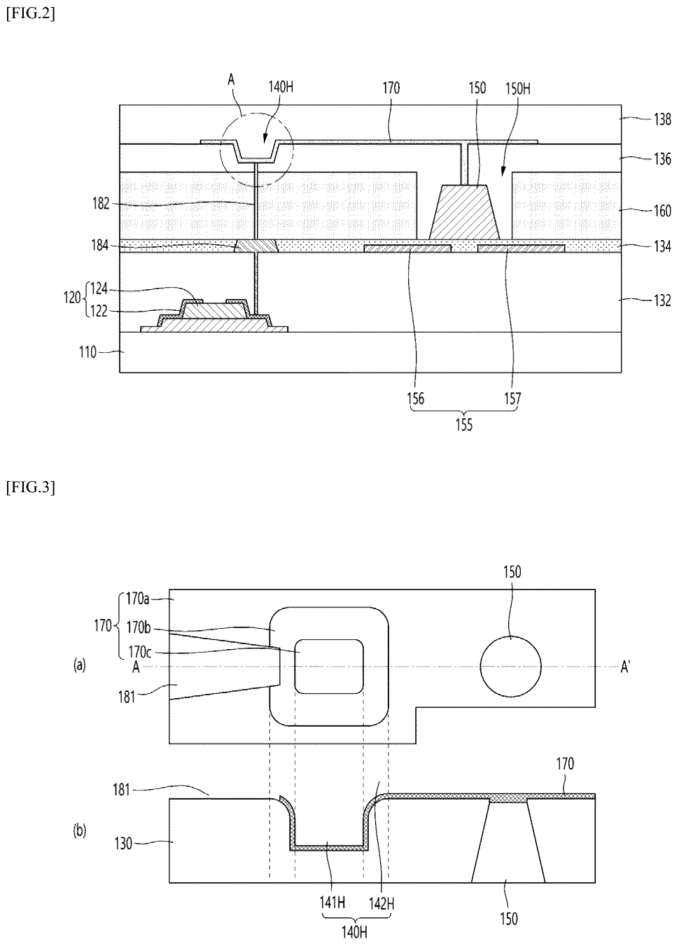

FIG. 2 relates to a display device including a semiconductor light emitting device according to the first embodiment. Referring to FIG. 2, a transistor 120 can be disposed on a substrate 110. The transistor 120 can include a gate electrode 124 and source/drain electrodes 122. The source/drain electrode 122 can be connected to the first transparent connection electrode 170 by being connected to the second electrode 182 and the third electrode 184.

A first insulating layer 132 can be disposed to cover the transistor 120. An assembly wire 155 can be disposed on the first insulating layer 132. The assembly wire 155 can include a first assembly wire 156 and a second assembly wire 157 spaced apart from each other. The first assembling wire 156 and the second assembling wire 157 can be provided to generate dielectrophoretic force for assembling the light emitting device 150.

The assembly wire 155 can be formed of a light-transmitting electrode (ITO) or can include a metal material having excellent electrical conductivity. For example, the assembly wire 155 can be formed of at least one of Titanium (Ti), Chromium (Cr), Nickel (Ni), Aluminum (Al), Platinum (Pt), Gold (Au), Tungsten (W) or Molybdenum (Mo) or an alloy thereof. A second insulating layer 134 can be disposed on the assembly wire 155 to cover the assembly wire 155.

Next, a barrier wall 160 can be disposed on the second insulating layer 134. The barrier wall 160 can be disposed to have an assembly hole 150H, and the semiconductor light emitting device can be assembled by an assembly wire 155 in the assembly hole 150H.

The semiconductor light emitting device 150 assembled in the assembly hole 150H may include a first conductivity type semiconductor layer, a second conductivity type semiconductor layer, and an active layer disposed therebetween. The first conductivity type semiconductor layer can be an n-type semiconductor layer, and the second conductivity type semiconductor layer may be a p-type semiconductor layer, but is not limited thereto. The first conductivity-type semiconductor layer, the active layer, and the second conductivity-type semiconductor layer can be made of a compound semiconductor material. For example, the compound semiconductor material may be a Group 3-5 compound semiconductor material, a Group 2-6 compound material, or the like. For example, the compound semiconductor material can include GaN, InGaN, AlN, AlInN, AlGaN, AlInGaN, InP, GaAs, GaP, GaInP, and the like.

Meanwhile, a third insulating layer 136 can be disposed to cover the semiconductor light emitting device 150 and the barrier wall 160. The third insulating layer 136 can planarize an upper portion of the substrate 110 on which the semiconductor light emitting device 150 is disposed, and the semiconductor light emitting device 150 can be stably fixed inside the assembly hole 150H by the third insulating layer 136.

Meanwhile, a first transparent connection electrode 170 can be disposed on the semiconductor light emitting device 150. The first transparent connection electrode 170 can electrically connect the semiconductor light emitting device to the transistor 120. In addition, the first transparent connection electrode 170 can be formed of a light-transmitting material, for example, ITO (Indium Tin Oxcide), but is not limited thereto.

In FIG. 2, area A is an area where the contact hole 140H is formed in the third insulating layer 136. The first transparent connection electrode 170 is disposed in the contact hole 140H and can electrically connect the transistor 120 and the semiconductor light emitting device, and the first transparent connection electrode 170 can include a recess pattern (not shown) disposed in a stepped region.

FIG. 3 is a plan view and a cross-sectional view showing area A in FIG. 2.

Referring to FIG. 3, a first transparent connection electrode 170 can be disposed on the insulating layer 130 covering the semiconductor light emitting device 150. The insulating layer 130 can include a contact hole 140H through which the first transparent connection electrode 170 is electrically connected to the transistor. The contact hole 140H can include a first contact hole 141H, which is a bottom surface of the contact hole, and a second contact hole 142H positioned on a side surface of the contact hole. The second contact hole 142H can have a curved surface.

A step exists in the insulating layer 130 due to the contact hole 140H, and the first transparent connection electrode 170 can in addition be disposed along the step. The stepped surface can have a constant curvature and can have a vertical slope.

In addition, the first transparent connection electrode 170 can include a first-first transparent connection electrode 170a, a first-second transparent connection electrode 170b, and a first-third transparent connection electrode 170c.

The first-first transparent connection electrode 170a can be disposed on the uppermost surface of the insulating layer 130. The first-second transparent connection electrode 170b can be disposed on the second contact hole 142H. The first-third transparent connection electrodes 170c can be disposed on the first contact hole 141H.

Meanwhile, a recess pattern 181 can be formed in the first transparent connection electrode 170. The recess pattern 181 may be a region where the insulating layer 130 is exposed when the first transparent connection electrode 170 is patterned on the insulating layer 130.

The recess pattern 181 can be patterned using a mask when forming the first transparent connection electrode 170. Alternatively, a recess pattern can be formed by depositing and then etching the first transparent connection electrode 170 on the insulating layer 130. A side surface of the contact hole 140H can have a curved surface, and when etching the contact hole 140H, the curved area can be etched by tilting the substrate or changing exposure conditions.

Meanwhile, the first transparent connection electrode 170 disposed on the insulating layer 130 can be damaged by temperature or pressure in a display panel process, and cracks can occur due to damage concentrated in a specific area. Accordingly, by forming a recess pattern in the first transparent connection electrode 170, it is possible to prevent damage from being concentrated on a specific area and to prevent cracks from occurring.

In particular, the first transparent connection electrode 170 can be easily cracked due to stress concentration in the sloped second contact hole 142H region. Accordingly, the recess pattern 181 is formed in the area of the second contact hole 142H to relieve stress applied to the first transparent connection electrode 170 and to prevent cracking.

Accordingly, the first embodiment has a technical effect of preventing damage from external stress by forming a recess pattern in the first transparent connection electrode 170, and there is a technical effect of preventing lighting errors and weak lights of the semiconductor light emitting device by improving the electrical connection reliability of the transistor and the semiconductor light emitting device.

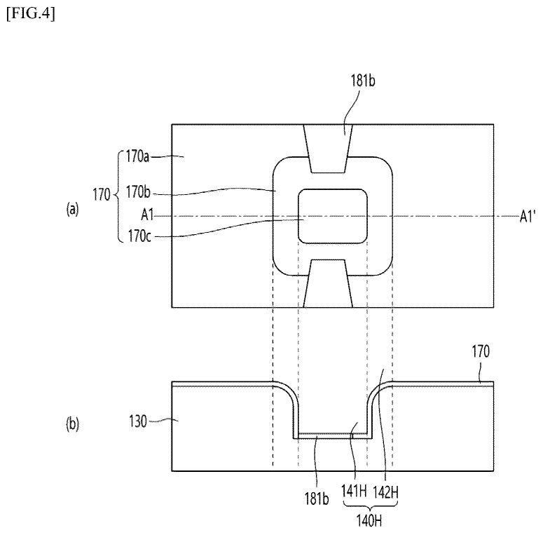

FIG. 4 is a conceptual diagram of a display device including the semiconductor light emitting device according to a second embodiment. FIG. 4(a) is a plan view showing a contact area, and FIG. 4(b) is a cross-sectional view of line A1-A1′ in (a).

The second embodiment can employ the technical features of the first embodiment described above, and the main features of the second embodiment will be mainly described below.

Referring to (a) of FIG. 4, a second recess pattern 181b can be formed on the first transparent connection electrode 170. The second recess pattern 181b can be formed on the first-first transparent connection electrode 170a and the first-second transparent connection electrode 170b. In addition, the second recess pattern 181b can include a plurality, and can be formed symmetrically with respect to the contact hole 140H.

Referring to (b) of FIG. 4, the first transparent connection electrode 170 can be disposed on the insulating layer 130 having the contact hole 140H, the second recess pattern 181b of the first transparent connection electrode 170 can be formed on the first-first transparent connection electrode 170a. The second recess pattern 181b can be formed from the first-first transparent connection electrode 170a to the interface between the first-first transparent connection electrode 170a and the first-second transparent connection electrode 170b.

Accordingly, the second embodiment has a technical effect of relieving external stress applied to the first transparent connection electrode and preventing cracks from occurring by forming the second recess pattern 181b on the boundary surface of the contact hole.

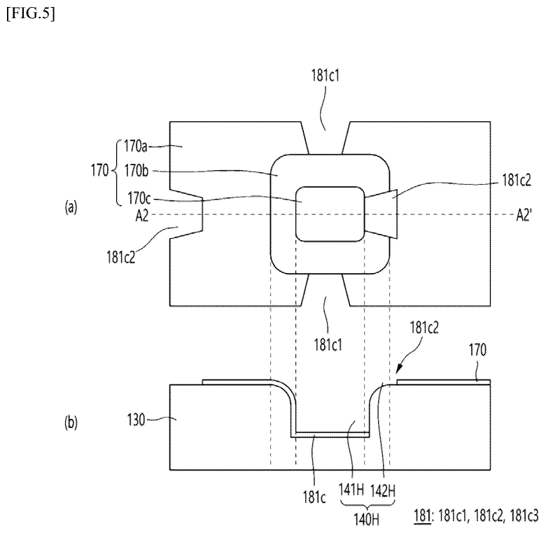

FIG. 5 is a conceptual diagram of a display device including the semiconductor light emitting device according to a third embodiment. FIG. 5(a) is a plan view illustrating a contact area, and FIG. 5(b) is a cross-sectional view along line A2-A2′ of FIG. 5(a).

The third embodiment can employ the technical features of the first or second embodiment described above, and the main features of the third embodiment will be mainly described below. Referring to (a) of FIG. 5, a third recess pattern 181 can be formed on the first transparent connection electrode 170. The third recess pattern 181c can include a plurality. For example, the third recess pattern 181c can include a third-first recess pattern 181c1, a third-second recess pattern 181c2, and a third-third recess pattern 181c3.

For example, the plurality of third-third recess patterns 181cl can be disposed on the first-first transparent connection electrode 170a and the first-second transparent connection electrode 170b. The plurality of third-first recess patterns 181cl can be formed in pairs to face each other and can have the same area.

In addition, the third-second recess pattern 181c2 is disposed on the second contact hole 142H area to mitigate the impact caused by thermal expansion in the stepped region to prevent cracking.

In addition, the third-third recess pattern 181c3 can be disposed on the first-first transparent connection electrode 170a.

Referring to (b) of FIG. 5, a plurality of third-first recess patterns 181cl can be formed on the insulating layer 130 and the contact hole 140H. In addition, the third-second recess pattern 181c2 can be formed on the second contact hole 142H. Accordingly, the third embodiment has a technical effect of relieving stress applied to the first transparent connection electrode 170 and preventing cracks by forming a plurality of third recess patterns 181c on the insulating layer 130 and the contact hole 140H.

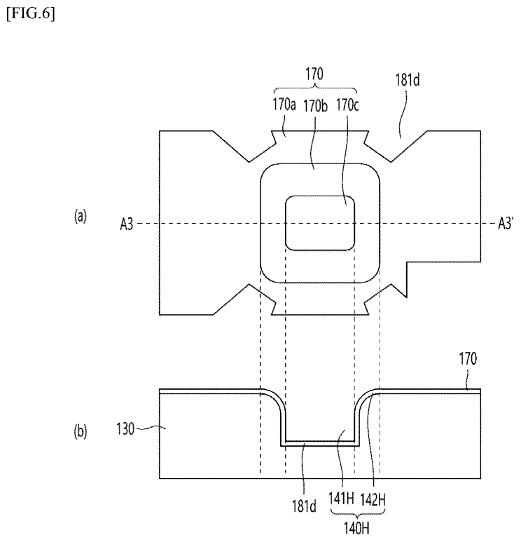

FIG. 6 is a conceptual diagram of a display device including the semiconductor light emitting device according to a fourth embodiment. FIG. 6(a) is a plan view illustrating a contact area, and FIG. 6(b) is a cross-sectional view along line A3-A3′ of FIG. 6(a).

The fourth embodiment can employ the technical features of the first to third embodiments described above, and the main features of the fourth embodiment will be mainly described below.

Referring to (a) and (b) of FIG. 6, a fourth recess pattern 181d can be formed on the first transparent connection electrode 170. In addition, a recess pattern (not shown) can be formed in the contact area. The fourth recess pattern 181d can include a plurality. The plurality of fourth recess patterns 181d can be formed to be close to the edge of the contact hole 140H, and can be symmetrically formed in pairs with respect to the contact hole 140H.

Therefore, the fourth embodiment has a technical effect of preventing cracks from occurring in the first transparent connection electrode by forming a plurality of fourth recess patterns 181d near each corner of the contact hole 140H.

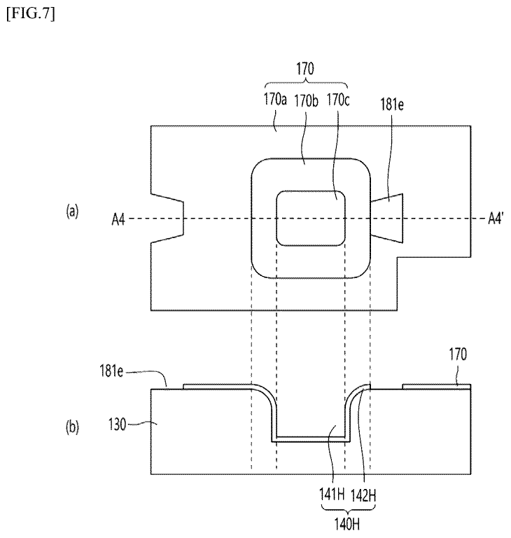

FIG. 7 is a conceptual diagram of a display device including a semiconductor light emitting device according to a fifth embodiment. FIG. 7(a) is a plan view showing the contact area, and FIG. 7(b) is a cross-sectional view of line A4-A4′ in (a).

The fifth embodiment can employ the technical features of the first to fourth embodiments described above, and the main features of the fifth embodiment will be mainly described below.

Referring to (a) of FIG. 7, a fifth recess pattern 181e can be formed on the first transparent connection electrode 170. The fifth recess pattern 181e can include a plurality. The plurality of fifth recess patterns 181e can be formed on the first-first transparent connection electrode 170a. In addition, the fifth recess pattern 181e can be formed at a boundary between the first and second transparent connection electrodes 170b disposed on the second contact hole 142H.

Referring to (b) of FIG. 7, the fifth recess pattern 181e can be formed to contact the boundary of the second contact hole 142H. The first-third transparent connection electrode 170c and the first-second transparent connection electrode 170b disposed on the first contact hole 141H and the second contact hole 142H can come into contact with each other, but one surface of the first-second transparent connection electrode 170b can be spaced apart from the first-first transparent connection electrode 170a. Therefore, the embodiment has a technical effect of preventing cracks of the first transparent connection electrode by forming a recess pattern on the boundary of the first transparent connection electrode disposed in the stepped region.

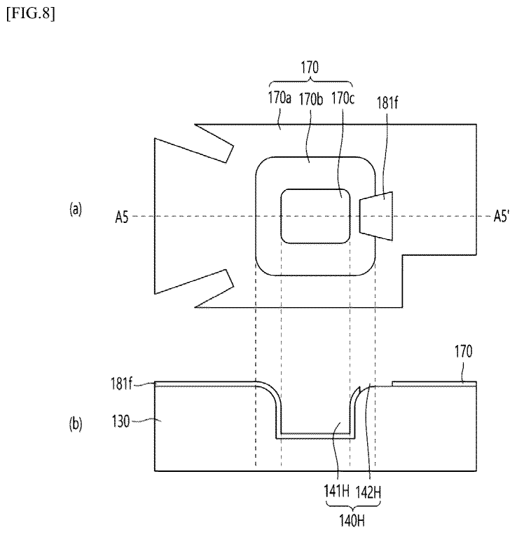

FIG. 8 is a conceptual diagram of a display device including the semiconductor light emitting device according to a sixth embodiment. FIG. 8(a) is a plan view illustrating a contact area, and FIG. 8(b) is a cross-sectional view along line A5-A5′ of FIG. 8(a).

The sixth embodiment can employ the technical features of the first to fifth embodiments described above, and the main features of the sixth embodiment will be mainly described below.

Referring to (a) of FIG. 8, a sixth recess pattern 181f can be formed on the first transparent connection electrode 170. The sixth recess pattern 181f can include a plurality. The plurality of sixth recess patterns 181f can be formed on the first-first transparent connection electrode 170a and the first-second transparent connection electrode 170b. The plurality of sixth recess patterns 181f can be formed symmetrically with respect to the line A5-A5′. In addition, the plurality of sixth recess patterns 181f can have different areas.

Referring to (b) of FIG. 8, the sixth recess pattern 181f can be formed outside the second contact hole 142H and the contact hole 140H. At least one of the plurality of sixth recess patterns 181f can be formed on the contact hole 140H to extend outwardly of the contact hole 140H. In addition, at least one of the plurality of sixth recess patterns 181f can be arranged to be close to the outside of the contact hole 140H. Accordingly, according to the embodiment, as the plurality of sixth recess patterns are arranged to extend to the contact hole and the outside of the contact hole, there is a technical effect of alleviating stress applied to the first transparent connection electrode in the contact area.

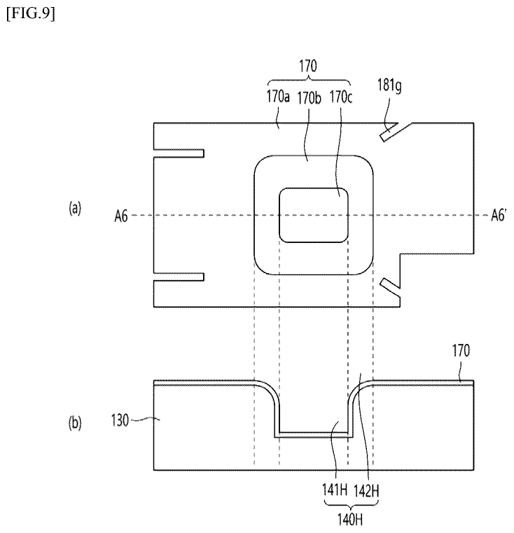

FIG. 9 is a conceptual diagram of a display device including the semiconductor light emitting device according to a seventh embodiment. FIG. 9(a) is a plan view illustrating a contact area, and FIG. 9(b) is a cross-sectional view along line A6-A6′ of FIG. 9(a).

The seventh embodiment can employ the technical features of the above-described first to sixth embodiments, and the main features of the seventh embodiment will be mainly described below. Referring to (a) and (b) of FIG. 9, a seventh recess pattern 181g can be formed on the first transparent connection electrode 170. In addition, a recess pattern (not shown) can be formed in the contact area. The seventh recess pattern 181g can include a plurality of pieces. The plurality of seventh recess patterns 181g can be formed on the first-first transparent connection electrode 170a and can be formed symmetrically with respect to the line A6-A6′. In addition, the plurality of seventh recess patterns 181g can be spaced apart from the contact area, and one end can be formed toward the stepped region. In addition, some of the plurality of seventh recess patterns 181g can be disposed parallel to each other.

Therefore, according to the embodiment, the recess pattern is arranged with one end facing the stepped region on the outside of the contact hole, thereby having a technical effect of dispersing the impact received by the transparent connection electrode in the stepped region and preventing cracks.

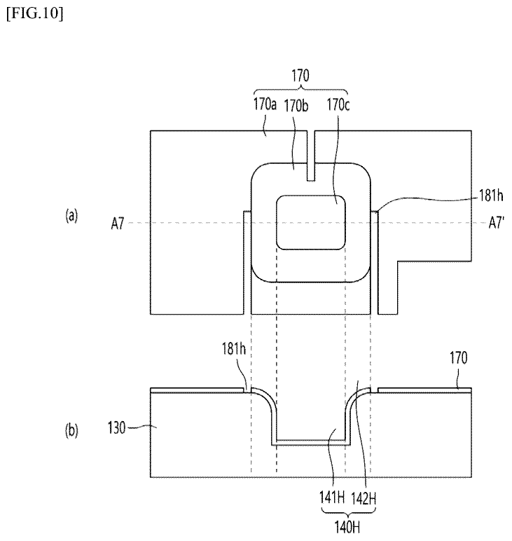

FIG. 10 is a conceptual diagram of a display device including the semiconductor light emitting device according to an eighth embodiment. (a) is a plan view showing the contact area, and (b) is a cross-sectional view of the A7-A7′ line in (a).

The eighth embodiment can employ the technical features of the first to seventh embodiments described above, and the main features of the eighth embodiment will be mainly described below.

Referring to (a) of FIG. 10, an eighth recess pattern 181h can be formed on the first-first transparent connection electrode 170a and the first-second transparent connection electrode 170b. The eighth recess pattern 181h can be formed parallel to one direction of the contact area. In addition, the eighth recess pattern 181h can be formed along the boundary of the contact hole. The first-second transparent connection electrode 170b disposed in the stepped region of the insulating layer can include a region in contact with the eighth recess pattern 181h and a region not in contact with the eighth recess pattern 181h.

Referring to (b) of FIG. 10, an eighth recess pattern 181h can be disposed at a boundary of the second contact hole 142H. Any one of the eighth recess patterns 181h can be formed from the upper surface of the insulating layer 130 to the sidewall of the contact hole 140H, and any one of the eighth recess patterns 181h can be disposed parallel to the contact hole 140H.

Therefore, in the embodiment, a recess pattern is formed parallel to the contact hole on the inside and boundary of the contact area, there is a technical effect of mitigating an impact applied to the first transparent connection electrode disposed in the contact area and preventing cracks.

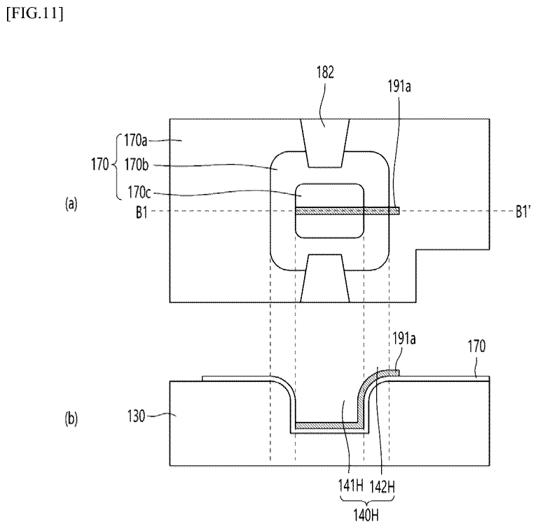

FIG. 11 is a diagram illustrating a contact area in a display device including the semiconductor light emitting device according to a ninth embodiment. FIG. 11(a) is a plan view illustrating a contact area, and FIG. 11(b) is a cross-sectional view taken along line B1-B1′ of FIG. 11(a).

The ninth embodiment can employ the technical features of the first to eighth embodiments described above, and the main features of the ninth embodiment will be mainly described below.

Referring to (a) of FIG. 11, a recess pattern 182 can be formed on the first transparent connection electrode 170. The recess pattern 182 can be formed on the second contact hole 142H and can be symmetrically disposed with respect to the first contact hole 141H.

In addition, a first metal pattern layer 191a can be disposed on the first transparent connection electrode 170. In order to increase adhesion when depositing the first metal pattern layer 191a on the first transparent connection electrode 170, the surface of the first transparent connection electrode 170 can be surface treated with plasma using O 2, Ar, N 2 or the like or HMDS coating. The first metal pattern layer 191a can be deposited on the surface of the first transparent connection electrode 170 through surface treatment. The first metal pattern layer 191a may not affect the luminance of the semiconductor light emitting device because it does not overlap with the semiconductor light emitting device.

The first metal pattern layer 191a can be disposed on the first transparent connection electrode 170. In detail, the first metal pattern layer 191a can be disposed on the first-first transparent connection electrode 170a, the first-second transparent connection electrode 170b, and the first-third transparent connection electrode 170c, and the first-first transparent connection electrode 170a, the first-second transparent connection electrode 170b, and the first-third transparent connection electrode 170c can be electrically connected. Accordingly, even if a crack occurs in the first transparent connection electrode 170, electrical connection is possible through the first metal pattern layer 191a. Therefore, in the embodiment, the first metal pattern layer 191a is disposed on the first transparent connection electrode 170 to have a technical effect of solving problems of lighting failure and weak light of the semiconductor light emitting device.

In addition, referring to FIG. 11(b), the first metal pattern layer 191a can be disposed on the first contact hole 141H and the second contact hole 142H. In particular, the first contact hole 141H and the second contact hole 142H can be regions in which stress is concentrated on the first transparent connection electrode 170 due to a step difference. Accordingly, the first metal pattern layer 191a is deposed on the first-second transparent connection electrode 170b and the first-third transparent connection electrode 170c disposed in the first contact hole 141H and the second contact hole 142H, a decrease in reliability of the transparent connection electrode can be prevented.

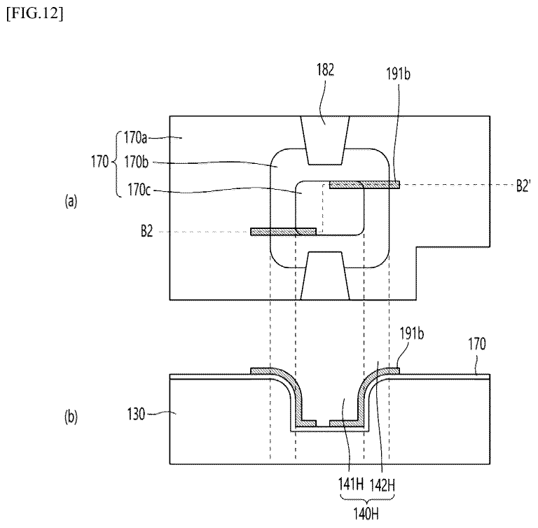

FIG. 12 is a diagram illustrating a contact area in a display device including the semiconductor light emitting device according to a tenth embodiment. FIG. 12(a) is a plan view illustrating a contact area, and FIG. 12(b) is a cross-sectional view taken along line B2-B2′ of FIG. 12(a).

The tenth embodiment can employ technical features of the first to ninth embodiments, and the main features of the tenth embodiment will be mainly described. Referring to (a) of FIG. 12, a recess pattern 182 is formed on the first-first transparent connection electrode 170a and the first-second transparent connection electrode 170b, stress applied to the first transparent connection electrode 170 in the stepped region can be alleviated and cracks can be prevented. In addition, in the embodiment, the second metal pattern layer 191b can be disposed on the first transparent connection electrode 170. The second metal pattern layer 191b can be disposed to pass through the first-first transparent connection electrode 170a, the first-second transparent connection electrode 170b, and the first-third transparent connection electrode 170c. The second metal pattern layer 191b can include a plurality of pieces. The plurality of second metal pattern layers 191b can be disposed to extend in opposite directions from each other on the first to third transparent connection electrodes 170c.

Referring to (b) of FIG. 12, the second metal pattern layer 191b can be disposed inside and outside the contact hole 140H. The second metal pattern layer 191b can be disposed on the first transparent connection electrode 170 disposed on the insulating layer 130. The plurality of second metal pattern layers 191b can be disposed on the first contact hole 141H to extend outwardly from the contact hole 140H in opposite directions.

Therefore, in the embodiment, as the plurality of second metal pattern layers 191b are disposed to extend to the inside and outside of the contact hole, respectively, there is a technical effect of preventing a decrease in reliability due to cracks in the transparent connection electrode.

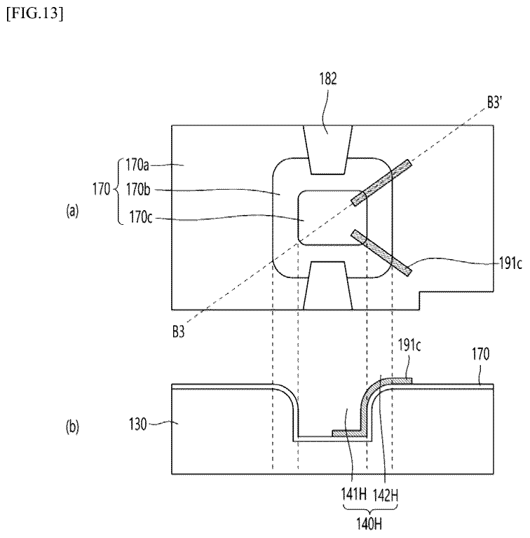

FIG. 13 is a diagram illustrating a contact area in a display device including the semiconductor light emitting device according to an eleventh embodiment. FIG. 13(a) is a plan view illustrating a contact area, and FIG. 13(b) is a cross-sectional view of line B3-B3′ in (a).

The eleventh embodiment can employ technical features of the first to tenth embodiments, and the main features of the eleventh embodiment will be mainly described below.

Referring to (a) of FIG. 13, a recess pattern 182 is formed on the first-first transparent connection electrode 170a and the first-second transparent connection electrode 170b, stress applied to the first transparent connection electrode 170 in the stepped region can be alleviated and cracks can be prevented.

In addition, in the embodiment, the third metal pattern layer 191c can be disposed on the first transparent connection electrode 170. The third metal pattern layer 191c can be disposed on the first-first transparent connection electrode 170a, the first-second transparent connection electrode 170b, and the first-third electrode. In addition, the third metal pattern layer 191c can be disposed to form a predetermined angle with the recess pattern 182.

Referring to (b) of FIG. 13, the third metal pattern layer 191c can be disposed in the first contact hole 141H and the second contact hole 142H. In addition, the third metal pattern layer 191c can be disposed on one side of the contact hole 140H. Therefore, the embodiment has a technical effect of concentrating and disposing the metal pattern layer in an area more vulnerable to external stress in the stepped region and preventing a decrease in electrical reliability even if the first transparent connection electrode disposed in the stepped region is damaged or cracked.

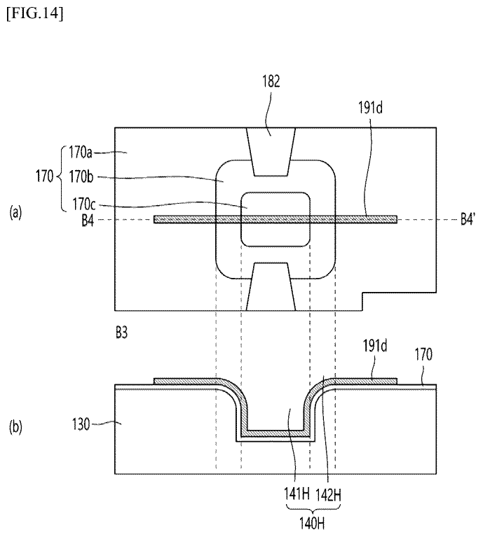

FIG. 14 is a diagram illustrating a contact area in a display device including the semiconductor light emitting device according to a twelfth embodiment. FIG. 14(a) is a plan view illustrating the contact area, and FIG. 14(b) is a cross-sectional view of line B4-B4′ of (a).

The twelfth embodiment can employ technical features of the first to eleventh embodiments, and the main features of the twelfth embodiment will be mainly described below.

Referring to (a) of FIG. 14, a recess pattern 182 is formed on the first-first transparent connection electrode 170a and the first-second transparent connection electrode 170b, stress applied to the first transparent connection electrode 170 in the stepped region can be alleviated and cracks can be prevented. In addition, in the embodiment, a fourth metal pattern layer 191d can be disposed on the first transparent connection electrode 170. The fourth metal pattern layer 191d can be disposed across between the recess patterns 182.

In addition, referring to FIG. 14(b), the fourth metal pattern layer 191d can be disposed across the contact hole 140H. The fourth metal pattern layer 191d has a length greater than the width of the contact hole 140H and can be disposed along the upper surface of the first transparent connection electrode 170 disposed along the step of the insulating layer 130. The fourth metal pattern layer 191d can have the same curvature as the insulating layer 130 and the first transparent connection electrode 170.

Accordingly, in the embodiment, since the fourth metal pattern layer is disposed across the contact hole along the first transparent connection electrode, there is a technical effect of preventing a decrease in electrical reliability of the first transparent connection electrode. Therefore, according to the embodiment, stress can be alleviated by patterning an electrode disposed in a region vulnerable to stress.

For example, according to the embodiment, a recess pattern can be formed in the contact area to prevent cracking.

For example, according to the embodiment, a recess pattern is formed in the contact area to prevent cracking.

In addition, the embodiment has a technical effect of preventing damage by alleviating the stress applied to the transparent connection electrode in the contact area of the semiconductor light emitting device and the transistor.

In addition, the embodiment has a technical effect of preventing a decrease in reliability of the transparent connection electrode due to a step in the contact area.

For example, according to the embodiment, a recess pattern is formed inside or outside the stepped region to prevent damage to the transparent connection electrode.

In addition, the embodiment has a technical effect of preventing a decrease in electrical reliability even when a crack is generated in the contact area.

For example, according to the embodiment, a metal pattern layer can be formed in the contact area to maintain electrical connection between the transparent connection electrodes.

The above detailed description should not be construed as limiting in all respects and should be considered as illustrative. The scope of the embodiments should be determined by reasonable interpretation of the appended claims, and all changes within the equivalent range of the embodiments are included in the scope of the embodiments.

* Explanation of reference signs

| | |
|---|---|
| 50, 150: semiconductor | 60, 130: insulating layer |
| light-emitting device | |
| 40H, 140H: contact hole | 70: upper electrode |
| 75: crack | 110: substrate |
| 120: transistor | 122: source/drain electrode |
| 124: gate electrode | 132: first insulating layer |
| 134; second insulating layer | 136: third insulating layer |
| 138: fourth insulating layer | 141H: first contact hole |
| 142H: second contact hole | 155: assembly wire |
| 156: first assembly wire | 157: second assembly wire |
| 160: barrier wall | 170: first transparent connection |
| | electrode |
| 170a: first-first transparent | |
| connecting electrode | |
| 170b: first-second transparent | |
| connecting electrode | |
| 170c: first-third connecting electrode | 181, 182: recess pattern |
| 191: metal pattern layer | |

What is claimed is:

1. A display device including a semiconductor light emitting device comprising:
a substrate;
a transistor disposed on the substrate;
a barrier wall disposed on the transistor and having an assembly hole;
a semiconductor light emitting device disposed within the assembly hole;
an insulating layer disposed on the semiconductor light emitting device and having a contact hole, and
a first transparent connection electrode disposed on the insulating layer and electrically connecting the semiconductor light emitting device and the transistor,
wherein the first transparent connection electrode comprises a recess pattern disposed in the contact hole.

2. The display device according to claim 1, wherein the recess pattern is disposed to contact the inner wall of the contact hole.

3. The display device according to claim 1, wherein a depth of the contact hole is configured to correspond to a height from a bottom surface to a top surface of the first transparent connection electrode.

4. The display device according to claim 1, wherein the recess pattern comprises a plurality of pieces, and
wherein the plurality of recess patterns are disposed symmetrically with respect to the contact hole.

5. The display device according to claim 4, wherein the plurality of recess patterns are spaced apart by the same distance from the center of the contact hole.

6. The display device according to claim 1, wherein the contact hole comprises a first contact hole disposed on a bottom surface of the contact hole and a second contact hole disposed on a side surface of the contact hole; and
wherein the second contact hole has a predetermined slope.

7. The display device according to claim 6, wherein the recess pattern is disposed on the second contact hole.

8. The display device according to claim 6, wherein the second contact hole has a curved surface.

9. The display device according to claim 6, wherein a portion of the recess pattern has a slope equal to a predetermined slope of the second contact hole.

10. The display device according to claim 1, wherein the recess pattern further comprises a second recess pattern disposed adjacent to an outside of the contact hole.

11. The display device according to claim 1, wherein the first transparent connection electrode comprises a first-first transparent connection electrode disposed outside the contact hole and a first-second transparent connection electrode disposed inside the contact hole, and
wherein the recess pattern is in contact with the first-first transparent connection electrode and the first-second transparent connection electrode.

12. The display device according to claim 1, wherein the recess pattern is disposed adjacent to a boundary of the contact hole.

13. The display device according to claim 1, further comprising a metal pattern layer disposed on the first transparent connection electrode, and
wherein the metal pattern layer is disposed within the contact hole.

14. The display device according to claim 13, wherein the first transparent connection electrode comprises a first-first transparent connection electrode disposed outside the contact hole and a first-second transparent connection electrode disposed inside the contact hole, and
wherein the metal pattern layer is configured to electrically connect the first-first transparent connection electrode and the first-second transparent connection electrode.

15. The display device according to claim 13, wherein the metal pattern layer is configured not to vertically overlap the recess pattern.

16. The display device according to claim 13, wherein a length of the metal pattern layer is greater than a length of the contact hole.

17. The display device according to claim 13, wherein the metal pattern layer comprises a plurality, and
wherein the plurality of metal pattern layers are configured to symmetrically disposed with respect to the contact hole.

18. The display device according to claim 13, wherein a portion of the metal pattern layer has a same slope as that of the contact hole.

19. The display device according to claim 13, wherein a depth of the contact hole is equal to a height from a bottom surface to an uppermost surface of the metal pattern layer.

20. The display device according to claim 13, wherein the recess pattern comprises a plurality of pieces, and
wherein the metal pattern layer is disposed between the plurality of recess patterns.
